(19) United States
(12) Patent Application Publication
(10) Pub. No.: US 2025/0142728 A1
(43) Pub. Date: May 1, 2025

(54) COIL CARRIER BOARD AND MANUFACTURING METHOD THEREOF

(71) Applicant: PHOENIX PIONEER TECHNOLOGY CO., LTD., Hsinchu County (TW)

(72) Inventors: Che-Wei HSU, Hsinchu County (TW); Wen-Hung HU, Hsinchu County (TW); Shih-Ping HSU, Hsinchu County (TW)

(73) Assignee: PHOENIX PIONEER TECHNOLOGY CO., LTD., Hsinchu County (TW)

(21) Appl. No.: 18/927,787

(22) Filed: Oct. 25, 2024

(30) Foreign Application Priority Data
Oct. 27, 2023 (TW) 112141375

(51) Int. Cl. H05K 1/16; H05K 3/10; H05K 3/40; H05K 3/46

(52) U.S. Cl. CPC H05K 1/165; H05K 3/10; H05K 3/4007; H05K 3/4644

(57) ABSTRACT

Provided is a coil carrier board, including a base coil layer, a conductive layer stacked on and bonded to the base coil layer, at least one build-up coil layer stacked on and bonded to the conductive layer, and an opening connecting the base coil layer, the conductive layer and the build-up coil layer. The coil carrier board has thick copper, fine line spacing and appropriate rigidity by means of the build-up circuit process and the structural design of the insulating layer of a photosensitive dielectric material bonded with a thermosetting dielectric material. Accordingly, the high current-carrying efficiency of the coil carrier board is enhanced, and the overall structure of the coil carrier board has better flatness, rigidity and high interlayer alignment accuracy, thereby facilitating miniaturization and automated assembly production.

### BACKGROUND

### 1. Technical Field

The present disclosure relates to a coil carrier board, and more particularly, a coil carrier board for an optical device package, and a method of manufacturing the same.

### 2. Description of Related Art

With the booming development of the electronics industry, electronic products have gradually moved towards multifunctional, high-performance and tiny trends. Conventional image sensing packages can be integrated by system manufacturers into external devices such as printed circuit boards (PCBs) for applications such as digital still cameras (DSCs), digital video cameras (DVs), optical mice, mobile phones, fingerprint readers and other electronic products.

At present, mobile optical camera products require higher image resolution, and artificial jitter often causes vague images. Therefore, the existing optical electronic products are equipped with Optical Image Stabilization (OIS) devices, such as magnetic drive devices, to prevent hand shaking.

FIG. 1A and FIG. 1B are schematic cross-sectional views of a manufacturing method of a conventional magnetic drive device 1.

As shown in FIG. 1A, a support bracket 10 having a first through hole 100, a flexible circuit board 11 having a second through hole 110 and a circuit layer 111, a flexible coil board 12 having a third through hole 120, a notch 121 and four sets of planar coils 122 and a Hall sensor 15 are provided.

As shown in FIG. 1B, the flexible circuit board 11 and the flexible coil board 12 are bonded by an adhesive layer 13, and the flexible circuit board 11 and the support bracket 10 are bonded by an adhesive layer 14, such that the first through hole 100, the second through hole 110 and the third through hole 130 are aligned with each other to form a via 18. Contacts 123 of the flexible coil board 12 are electrically connected to the circuit layer 111 of the flexible circuit board 11 by a solder material 16. The Hall sensor 15 is accommodated in the notch 121 of the flexible coil board 12 and electrode pads 150 thereof are electrically connected to the flexible circuit board 11 by a solder material 17. The flexible circuit board 11 is a flexible board to be bent downwardly at the left and right sides and to be attached to side surfaces of the support bracket 11.

However, in the conventional magnetic drive device 1, the flexible coil board 12 is made of a flexible material, resulting in poor flatness of the overall structure, such as an amplitude of concavity and convexity of more than 150 micrometers (μm), and poor alignment accuracy between the layers, such as an error of more than 100 micrometers. As such, it is necessary to manufacture a larger planar coil 122, which makes it difficult to miniaturize the flexible coil board 12. For example, it is difficult to manufacture a coil carrier board with a board area smaller than 5×5 mm².

In addition, the structure of the flexible coil board 12 made of a flexible material is too soft and thus prone the problem of misalignment during the assembly of electronic products, thereby resulting in the flexible coil board 12 not being able to be guided into the automated production line of the magnetic drive device 1. Hence, the magnetic drive device 1 needs to manually assemble the flexible coil board 12, thereby making it difficult to fully automate the assembly and production of the magnetic drive device 1.

Therefore, how to overcome the various problems of the above-mentioned conventional technology has become an urgent issue for the industry to be solved.

### SUMMARY

In view of the various deficiencies of the prior art, the present disclosure provides a coil carrier board. The coil carrier board comprises: a base coil layer including a base planar spiral coil made of metal material and a first insulating layer covering the base planar spiral coil; a conductive layer stacked on and bonded to the based coil layer, wherein the conductive layer includes a conductor made of metal material and a second insulating layer covering the conductor; at least one build-up coil layer stacked on and bonded to the conductive layer, wherein the at least one build-up coil layer includes a build-up planar spiral coil made of metal material and a third insulating layer covering the build-up planar spiral coil, wherein an upper surface of the build-up planar spiral coil and a side circumference thereof are covered with at least one electroplated growth layer formed by metal material; and an opening penetrating the base coil layer, the conductive layer, and the build-up coil layer.

In the aforementioned coil carrier board, the at least one build-up coil layer further incudes a multiple-layer stacked build-up coil layer, and at least one conductor is included between two adjacent build-up coil layers to connect two build-up planar spiral coils in a relatively upper layer and a relatively lower layer.

In one embodiment of the coil carrier board of the present disclosure, a relatively uppermost layer of the build-up coil layer further includes at least one external electrical connection pad made of a metallic material

In one embodiment of the coil carrier board of the present disclosure, a lower surface of the first insulating layer is further bonded to a lower insulating layer including an insulating material.

In one embodiment of the coil carrier board of the present disclosure, the first insulating layer includes a photosensitive dielectric material, and the second insulating layer and/or the third insulating layer include(s) a thermosetting dielectric material.

In one embodiment of the coil carrier board of the present disclosure, the base planar spiral coil, the conductor, the build-up planar spiral coil and/or the electroplated growth layer include(s) copper or a copper alloy.

In one embodiment of the coil carrier board of the present disclosure, compositions of the electroplated growth layer and the build-up planar spiral coil are the same or different.

In one embodiment of the coil carrier board of the present disclosure, an upper surface of the base planar spiral coil protrudes from, is flush with, or is recessed into an upper surface of the first insulating layer.

The present disclosure further provides a method of manufacturing a coil carrier board, the method comprises: step 1, providing a carrier board having a metallic surface; step 2, forming a first insulating layer having patterned plurality of openings on the carrier board; step 3, forming a base planar spiral coil by electroplating in the patterned plurality of openings; step 4, forming a second insulating layer on the first insulating layer and the base planar spiral coil to cover the first insulating and the base planar spiral coil; step 5, forming at least one aperture in an upper surface of the second insulating layer to expose a portion of the upper surface of the base planar spiral coil; step 6, performing a surface metallization process to form a metallized surface on the upper surface of the second insulating layer and within the aperture to serve as an electroplating electrode; step 7, forming a build-up planar spiral coil on the second insulating layer and forming a conductor in the aperture for connecting the build-up planar spiral coil to the base planar spiral coil by electroplating on the metallized surface of the second insulating layer and the aperture by means of a patterned exposure developing process; step 8, performing an etching process to remove a material of the metallized surface on the second insulating layer that is not covered by the build-up planar spiral coil; step 9, forming an electroplated growth layer on exposed surfaces of the build-up planar spiral coil by performing an electroplating process to make the build-up planar spiral coil taller, wider and shorter in line pitch, wherein the number of repetitions of step 9 can be increased optionally to form a stack of a plurality of electroplated growth layers; step 10, forming a third insulating layer on the second insulating layer to cover the second insulating layer and the build-up planar spiral coil; step 11, removing the carrier board to expose a lower surface of the base planar spiral coil and a lower surface of the first insulating layer; and step 12, forming a through hole through the first insulating layer, the second insulating layer and the third insulating layer to form an opening.

In one embodiment of the method of the present disclosure, prior to performing step 11, step 10 further includes performing the following steps: step 10-1, forming at least one aperture in the third insulating layer to expose a portion of an upper surface of the build-up planar spiral coil; step 10-2, performing a surface metallization process to form a metallized surface on an upper surface of the third insulating layer and within the aperture; step 10-3, forming another build-up planar spiral coil and forming a conductor connecting the another build-up planar spiral coil to the build-up planar spiral coil that is below the another build-up planar spiral coil by electroplating on the metallized surface of the third insulating layer and the aperture by means of a patterned exposure developing process; step 10-4: performing an etching process to remove a metal material on the metallized surface of the third insulating layer that is not covered by the another build-up planar spiral coil, so as to expose an insulating surface of the third insulating layer; step 10-5, forming another electroplated growth layer on exposed surfaces of the another build-up planar spiral coil by performing an electroplating process to make the another build-up planar spiral coil taller, wider and shorter in line pitch, wherein the number of repetitions of step 10-5 can be increased optionally to form a stack of a plurality of another electroplated growth layer; step 10-6, forming another third insulating layer to cover the another build-up planar spiral coil formed in step 10-3 through step 10-5; and step 10-7, optionally increasing the number of repetitions of steps 10-1 through step 10-6 to form a stack of a plurality of the another build-up planar spiral coil and the another third insulating layer.

In one embodiment of the method of the present disclosure, at least one external electrical connection pad is formed by simultaneous electroplating during a formation of the build-up planar spiral coil in an uppermost layer, and an upper surface of the external electrical connection pad is exposed from an upper surface of the third insulating layer in the uppermost layer.

In one embodiment of the method of the present disclosure, the method further includes prior to performing step 12, forming a lower insulating layer to cover the lower surface of the first insulating layer.

In one embodiment of the method of the present disclosure, compositions of the electroplated growth layer and the build-up planar spiral coil are the same or different.

In one embodiment of the method of the present disclosure, the upper surface of the second insulating layer in step 5 is a metallic surface or a non-metallic surface.

In one embodiment of the method of the present disclosure, the upper surface of the third insulating layer in step 10-2 is a metallic surface or a non-metallic surface.

In view of the above, in the coil carrier board and manufacturing method thereof of the present disclosure, the first insulating layer, the second insulating layer and the spiral coil are manufactured mainly by a build-up circuit process, such that the overall structure of the coil carrier board has excellent flatness, and the alignment accuracy between the layers is extremely high, and it is easy to manufacture a fine line width/fine line spacing. Therefore, compared to conventional flexible coil boards, the present disclosure is able to obtain a miniaturized coil carrier board with better flatness and higher alignment accuracy.

Furthermore, the present disclosure adopts a thermosetting dielectric material as the second insulating layer to strengthen the rigidity of the coil carrier board, thereby avoiding the problem of misalignment during the assembly of electronic products. Therefore, compared to the conventional flexible coil boards, the coil carrier board of the present disclosure is structurally rigid and can be introduced into the automatic production line of the electronic products (e.g., magnetic drive devices) to achieve the purpose of automated assembly production of electronic products (e.g., magnetic drive devices).

### BRIEF DESCRIPTION OF THE DRAWINGS

FIG. 1A and FIG. 1B are schematic cross-sectional views of a manufacturing method of a conventional magnetic drive device.

FIG. 2A to FIG. 2I are schematic cross-sectional views showing a method of manufacturing a coil carrier board according to a first embodiment of the present disclosure.

FIG. 2F-1 is a schematic cross-sectional view showing another manner of FIG. 2F.

FIG. 3A to FIG. 3D are schematic cross-sectional views showing a method of manufacturing a coil carrier board according to a second embodiment of the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

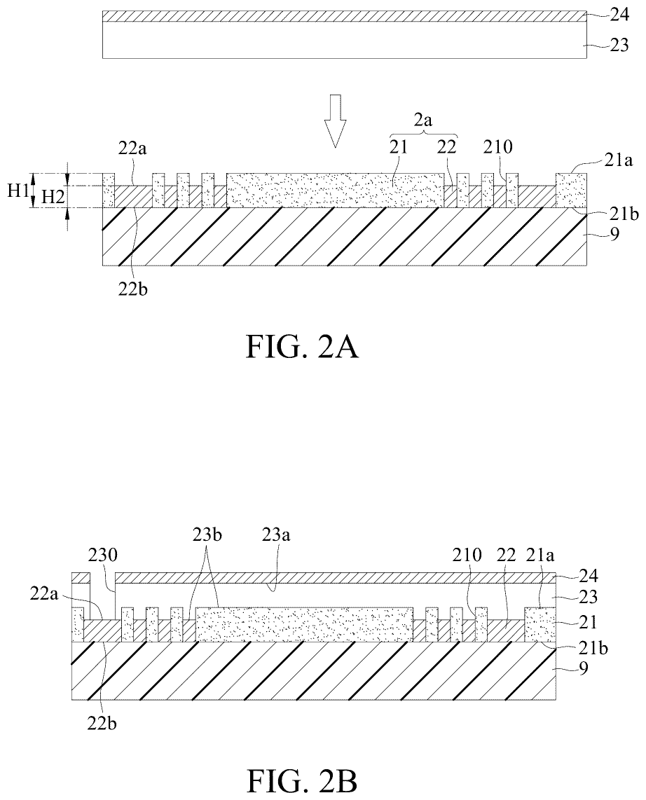

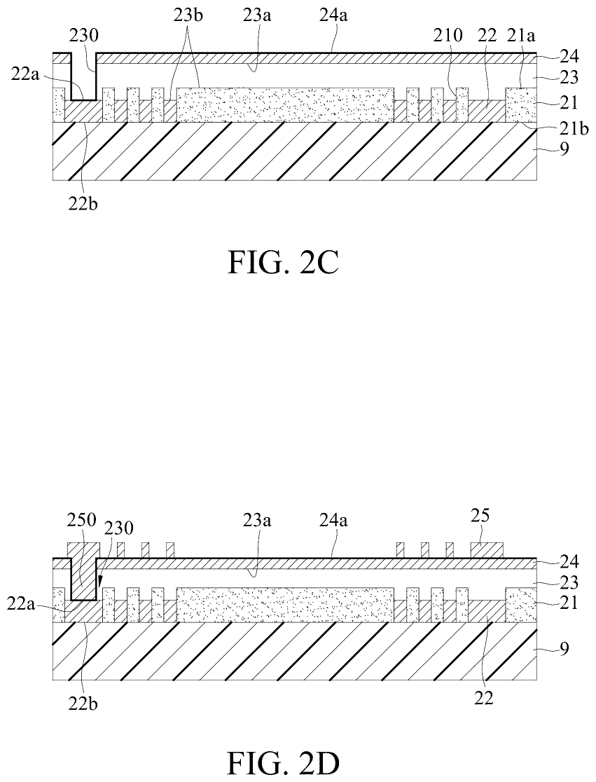

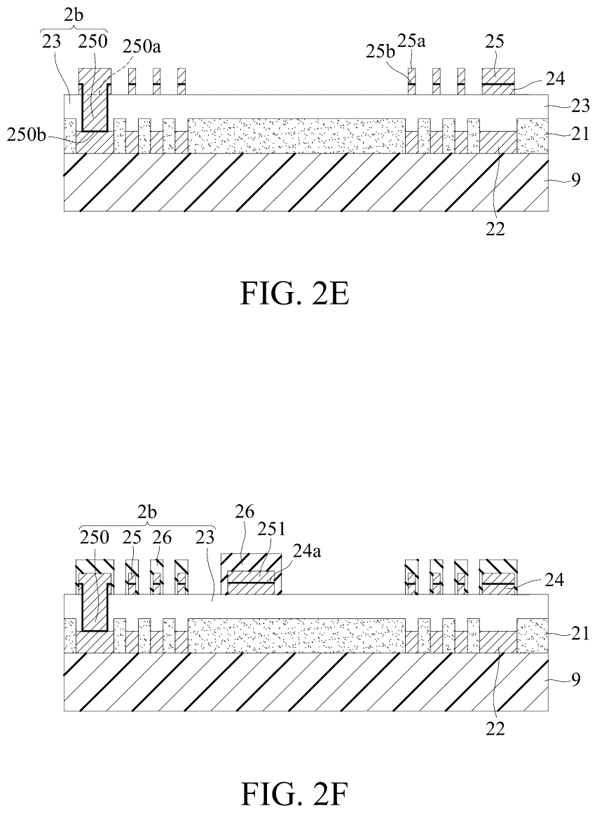

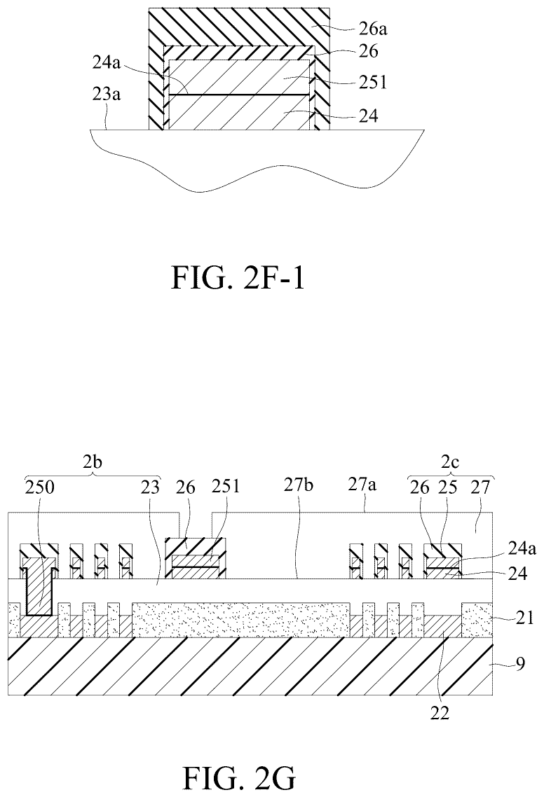

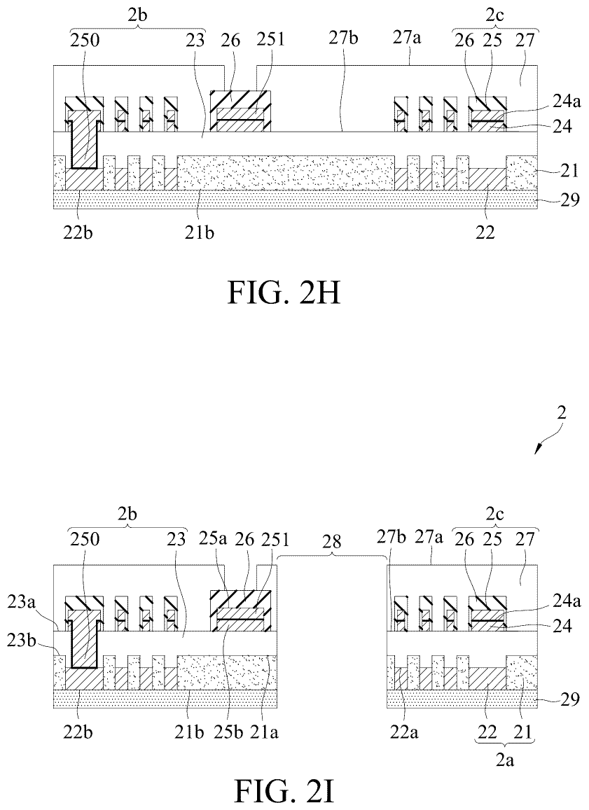

FIG. 2A to FIG. 2I are schematic cross-sectional schematic views showing a method of manufacturing a coil carrier board 2 according to a first embodiment of the present disclosure. In an embodiment, the coil carrier 2 board is used as an Optical Image Stabilization (OIS) carrier board for an electronic product.

As shown in FIG. 2A, a carrier board 9 having a metallic surface is provided, and a first insulating layer 21 having patterned plurality of openings 210 is than formed on the metallic surface of the carrier board 9. Subsequently, a metallic base planar spiral coil 22 is formed by electroplating in the patterned plurality of openings 210, whereby a base coil layer 2a is formed.

In an embodiment, the carrier board 9 is a separable metal board or a copper foil substrate, but not limited thereto, and in an embodiment, a metal board is illustrated with two sides having a separable and copper-containing metal material.

Moreover, the first insulating layer 21 has a second upper surface 21a and a second lower surface 21b opposing the second upper surface 21a, and covers the base planar spiral coil 22. For example, the material of forming the first insulating layer 21 is a photosensitive dielectric material including Ajinomoto build-up film (ABF), photosensitive resin, polyimide (PI), bismaleimide triazine (BT), prepreg (PP) of FR5, molding compound, or epoxy molding compound (EMC).

Further, the base planar spiral coil 22 has a first upper surface 22a and a first lower surface 22b opposing the first upper surface 22a. The first upper surface 22a of the base planar spiral coil 22 is exposed from the second upper surface 21a of the first insulating layer 21, and the first lower surface 22b of the base planar spiral coil 22 is bonded to the carrier board 9. For example, the base planar spiral coil 22 is manufactured in the same manner as the circuit layer of the packaging substrate, and the patterned copper layer may be manufactured by electroplating, sputtering, physical vapor deposition (PVD), etc.

In addition, a thickness H2 of the base planar spiral coil 22 may be less than, equal to, or greater than a thickness H1 of the first insulating layer 21. In an embodiment, the thickness H2 of the base planar spiral coil 22 is less than the thickness H1 of the first insulating layer 21, such that the first upper surface 22a of the base planar spiral coil 22 is lower than the opening end of the patterned plurality of openings 210, and the first upper surface 22a of the base planar spiral coil 22 is recessed into the second upper surface 21a of the first insulating layer 21. In other embodiments, the first upper surface 22a of the base planar spiral coil 22 protrudes from or is flush with the second upper surface 21a of the first insulating layer 21. In an embodiment, the first upper surface 22a of the base planar spiral coil 22 is perfectly recessed into the second upper surface 21a of the first insulating layer 21.

As shown in FIG. 2B, a second insulating layer 23 is pressed on the first insulating layer 21 and the base planar spiral coil 22. The second insulating layer 23 covers the first upper surface 22a of the base planar spiral coil 22, and the composition of the insulating material of the second insulating layer 23 is different from that of the insulating material of the first insulating layer 21. The second insulating layer 23 has a third upper surface 23a and a third lower surface 23b opposing the third upper surface 23a. Subsequently, at least one aperture 230 is formed in the third upper surface 23a of the second insulating layer 23 to expose a portion of the first upper surface 22a of the base planar spiral coil 22.

In an embodiment, the second insulating layer 23 may be an insulating material as a whole. Alternatively, the second insulating layer 23 may be a substrate having a metal layer 24 on a surface thereof. In an embodiment, the second insulating layer 23 is an insulating material having a metal layer 24 on the surface thereof (as shown in FIG. 2A), and the aperture 230 extends from the metal layer 24 through the second insulating layer 23 to a portion of the first upper surface 22a of the base planar spiral coil 22. For example, the second insulating layer 23 and the metal layer 24 are made from a resin coated copper (RCC) substrate.

Moreover, the insulating material of forming the second insulating layer 23 is different from the insulating material of forming the first insulating layer 21. For example, the insulating material of the second insulating layer 23 is a thermoset dielectric material.

Further, the first upper surface 22a of the base planar spiral coil 22 is recessed into the second upper surface 21a of the first insulating layer 21, such that there is a non-flat interface, such as a concave-convex interface, between the first insulating layer 21 and the second insulating layer 23. Therefore, the second insulation layer 23 is stacked on the first insulating layer 21 in a non-flat surface manner.

Alternatively, the aperture 230 may be manufactured by laser or etching, but not limited to the above.

As shown in FIG. 2C, a surface metallization process is performed to form a continuous metallized surface 24a on the metal layer 24 of the second insulating layer 23 and on the surface of the aperture 230. The metallized surface 24a serves as an electroplating electrode for a subsequent electroplating process.

As shown in FIG. 2D and FIG. 2E, a build-up planar spiral coil 25 made of metal material and a conductor 250 (made of metal material) formed in the aperture 230 for connecting the build-up planar spiral coil 25 to the base planar spiral coil 22 are formed by electroplating by means of a patterned exposure developing process, such that the second insulating layer 23 and the conductor 250 are used as a conductive layer 2b. Subsequently, an etching process is performed to remove the materials of the metallized surface 24a and the metal layer 24 on the second insulating layer 23 that is not covered by the build-up planar spiral coil 25, wherein the build-up planar spiral coil 25 has the same composition as the conductor 250.

In an embodiment, the build-up planar spiral coil 25 has a fourth upper surface 25a and a fourth lower surface 25b opposing the fourth upper surface 25a. For example, the build-up planar spiral coil 25 is manufactured in the same way as the circuit layer of the package substrate, by electroplating, sputtering, physical vapor deposition (PVD) or other means, and a portion of the metallized surface 24a and the metallic layer 24 are removed by etching.

Also, the conductor 250 has a first upper end surface 250a and a first lower end surface 250b opposing the first upper end surface 250a.

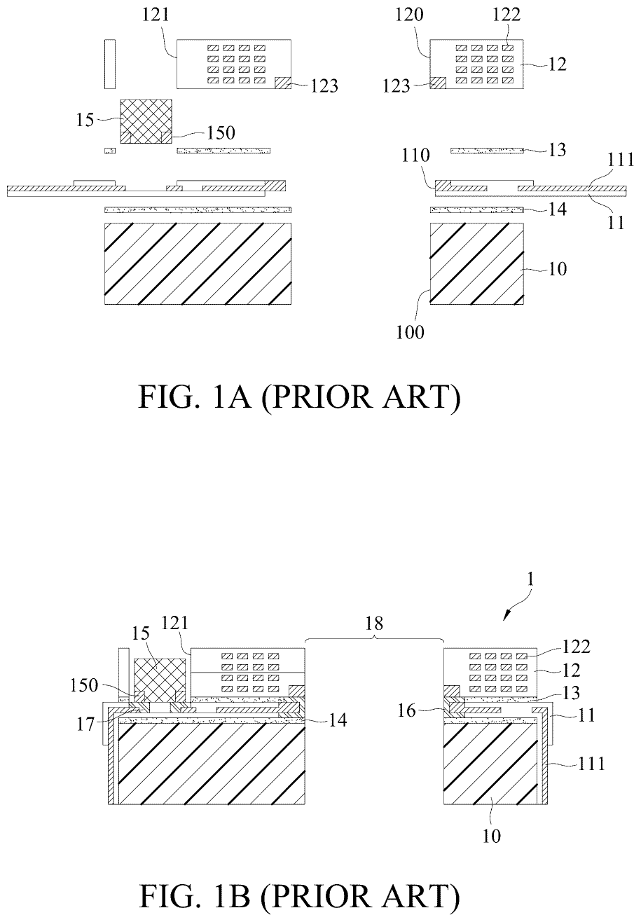

As shown in FIG. 2F, an electroplating process is performed to form an electroplated growth layer 26 on the exposed surface of the build-up planar spiral coil 25 to make the build-up planar spiral coil 25 taller, wider and shorter in line pitch. The number of repetitions of the electroplated growth layer 26 can be increased optionally to form a stack of a plurality of electroplated growth layers 26, as shown in FIG. 2F-1.

In an embodiment, at least one external electrical connection pad 251 is formed by simultaneous electroplating during a formation of the build-up planar spiral coil 25 in an uppermost layer.

Moreover, the compositions of the electroplated growth layer 26 and the build-up planar spiral coil 25 are the same or different. For example, the material of forming the electroplated growth layer 26 is copper. Accordingly, by the design of the electroplated growth layer 26 and the build-up planar spiral coil 25 being copper, the build-up planar spiral coil 25 and the electroplated growth layer 26 can be used as a coil body, and thus the coil body can utilize the electroplated growth layer 26 to increase the thickness of the copper, thereby reducing the distance between circuits (i.e., effectively reducing the spacing between circuits) of the coil body.

As shown in FIG. 2G, a third insulating layer 27 is pressed onto the second insulating layer 23 to cover the second insulating layer 23 and the build-up planar spiral coil 25 having the electroplated growth layer 26, so as to combine them and form a build-up coil layer 2c.

In an embodiment, the third insulating layer 27 has a fifth upper surface 27a and a fifth lower surface 27b opposing the fifth upper surface 27a and covers the build-up planar spiral coil 25. For example, the upper surface of the external electrical connection pad 251 having the electroplated growth layer 26 is exposed from the fifth upper surface 27a of the third insulating layer 27 (i.e., the uppermost layer).

In an embodiment, the third insulating layer 27 is composed of a photosensitive dielectric material, a non-photosensitive dielectric material, a thermosetting dielectric material, or a solder resist ink.

As shown in FIG. 2H, the carrier board 9 is removed to expose the second lower surface 21b of the first insulating layer 21 and the first lower surface 22b of the base planar spiral coil 22. Subsequently, a lower insulating layer 29 is formed to cover the second lower surface 21b of the first insulating layer 21 and the first lower surface 22b of the base planar spiral coil 22.

In an embodiment, the lower insulating layer 29 is composed of a photosensitive dielectric material, a non-photosensitive dielectric material, a thermosetting dielectric material, or a solder-resist ink, etc.

As shown in FIG. 2I, a through hole is formed through the first insulating layer 21, the second insulating layer 23 and the third insulating layer 27 to form an opening 28, which can penetrate through the lower insulating layer 29 as required.

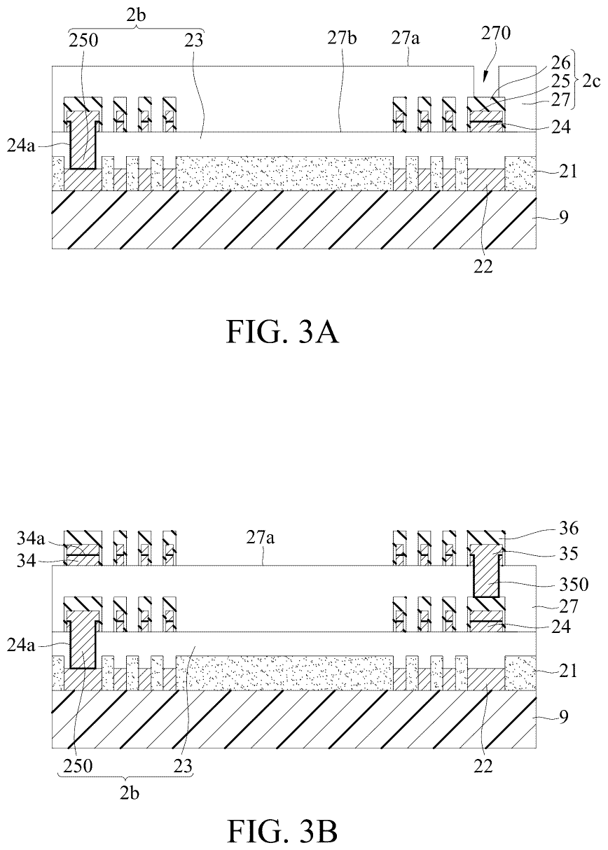

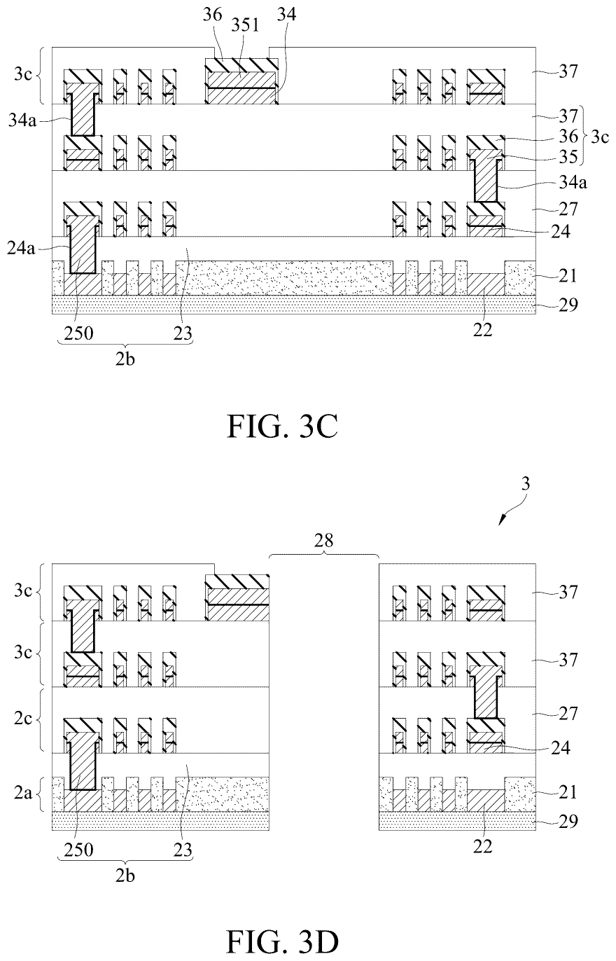

FIG. 3A to FIG. 3D are schematic cross-sectional views showing a method of manufacturing a coil carrier board 3 according to a second embodiment of the present disclosure. The difference between this embodiment and the first embodiment is in the number of coils manufactured, and the other processes are generally the same. Hence, the same will not be repeated.

As shown in FIG. 3A, in the process of FIG. 2G, at least one opening 270 is formed in the fifth upper surface 27a of the third insulating layer 27 to expose a portion of the surface of the build-up planar spiral coil 25 having the electroplated growth layer 26.

In an embodiment, the third insulating layer 27 may be an insulating material as a whole. Alternatively, the third insulating layer 27 may be a substrate (resin coated copper (RCC) foil substrate) having a metal layer 34 on a surface thereof. In an embodiment, the third insulating layer 27 is an insulating material having a metal layer 34 on a surface thereof, and in the manner shown in FIG. 2C, a surface metallization process is performed to form a continuous metallized surface 34a on the metal layer 34 of the third insulating layer 27 and on the surface of the opening, which serves as an electroplating electrode for a subsequent electroplating process.

As shown in FIG. 3B, on the fifth upper surface 27a of the third insulating layer 27, another build-up planar spiral coil 35 and a conductor 350 connecting the another build-up planar spiral coil 35 to the build-up planar spiral coil 25 (below the another build-up planar spiral coil 35) are formed by electroplating on the metallized surface 34a by means of a pattern exposure developing process, and an etching process is performed to remove the materials of the metalized surface 34a and the metal layer 34 on the third insulating layer 27 that is not covered by the another planar spiral coil 35, thereby exposing the insulating material.

Subsequently, an electroplating process is performed to form another electroplated growth layer 36 on the exposed surface of the another build-up planar spiral coil 35 to make the another build-up planar spiral coil 35 taller, wider and shorter in line pitch. The above mentioned performances may be optionally repeated for a number of times in order to form a stack of a plurality of another electroplated growth layers.

As shown in FIG. 3C, another third insulating layer 37 is formed on the third insulating layer 27 to cover the another build-up planar spiral coil 35. It should be appreciated that the number of times that another build-up coil layer 3c is performed can be optionally repeated to form a stack of another planar spiral coil 35 and the another third insulating layer 37. After that, the carrier board 9 is removed, and the lower insulating layer 29 is formed.

In an embodiment, the another third insulating layer 37 (i.e., the relatively uppermost (outer) layer) is composed of a photosensitive dielectric material, a non-photosensitive dielectric material, a thermosetting dielectric material, or a solder resist ink, and during a formation of an uppermost layer of the another build-up planar spiral coil 35, at least one external electrical connection pad 351 is formed by simultaneous electroplating, such that the electroplated growth layer 36 on the upper surface of the external electrical connection pad 351 is exposed from the another third insulating layer 37 (i.e., the uppermost layer).

As shown in FIG. 3D, a through hole is formed through the first insulating layer 21, the second insulating layer 23, and the third insulating layer 27, the another third insulating layer(s) 37 to form an opening 28, which can penetrate through the lower insulating layer 29 as required.

Accordingly, the manufacturing method of the present disclosure mainly manufactures the first insulating layer 21 and the second insulating layer 23 as well as the base planar spiral coil 22 and the build-up planar spiral coil 25 by means of the build-up circuit process, such that the overall structure of the coil carrier board 2 has excellent flatness, such as a an amplitude of concavity and convexity of less than 75 micrometers (μm), and the alignment accuracy between the layers is extremely high, such as an error of less than 50 micrometers, and it is easy to manufacture a fine line width/fine line interval. Therefore, the manufacturing method of present disclosure is able to obtain a miniaturized coil carrier board with better flatness and higher alignment accuracy, e.g., a board area of less than 5×5 mm², as compared to the conventional flexible coil boards.

Furthermore, the use of a photosensitive dielectric material as the first insulating layer 21 facilitates the manufacture of high aspect ratio patterned plural openings 210 for the attachment and forming of electroplated metals. Hence, the present disclosure is able to manufacture a base planar spiral coil 22 with optimized features such as copper thickness and fine pitch, thereby effectively enhancing the high current-carrying efficiency of the coil carrier board 2.

In addition, the horizontal build-up planar spiral coil 25, another build-up planar spiral coil 35 having electroplated growth layers 26, 36 can effectively increase the copper thickness and reduce the copper layer spacing by multiple copper electroplating processes, thereby effectively enhancing the high current-carrying efficiency of the coil carrier board 2.

Furthermore, the manufacturing method of the present disclosure adopts a thermosetting dielectric material as the second insulating layer 23 to strengthen the rigidity of the coil carrier board 2, thereby avoiding the problem of misalignment during the assembly of electronic products. Therefore, compared to the conventional flexible coil boards, the coil carrier board 2 of the present disclosure is structurally rigid and can be introduced into the automated production line of electronic products (such as magnetic drive devices) to achieve the purpose of automated assembly production of electronic products (such as magnetic drive devices).

The present disclosure also provides a coil carrier board 2, including: a base coil layer 2a, a conductive layer 2b which is stacked on and bonded to the base coil layer 2a, at least one build-up coil layer 2c, 3c which is stacked on and bonded to the conductive layer 2b, and an opening 28 connecting the base coil layer 2a, the conductive layer 2b and the build-up coil layer 2c, 3c.

The base coil layer 2a includes a base planar spiral coil 22 (made of metal material) having a first upper surface 22a and a first lower surface 22b opposing the first upper surface 22a, and includes a first insulating layer 21 covering the base planar spiral coil 22 and having a second upper surface 21a and a second lower surface 21b opposing the second upper surface 21a, wherein the first upper surface 22a of the base planar spiral coil 22 is exposed from the second upper surface 21a of the first insulating layer 21, and the first lower surface 22b of the base planar spiral coil 22 is exposed from the second lower surface 21b of the first insulating layer 21.

The conductive layer 2b includes a conductor 250 (made of metal material) having a first upper end surface 250a and a first lower end surface 250b opposing the first upper end surface 250a, and includes a second insulating layer 23 having a third upper surface 23a and a third lower surface 23b opposing the third upper surface 23a and covering the conductor 250, wherein the first upper end surface 250a of the conductor 250 is exposed from the third upper surface 23a of the second insulating layer 23, and the first lower end surface 250a of the conductor 250 is bonded to the first upper surface 22a of the base planar spiral coil 22. The second insulating layer 23 has a different composition from that of the first insulating layer 21. The third lower surface 23b of the second insulating layer 23 is stacked on and bonded to the second upper surface 21a of the first insulating layer 21, such that the second insulating layer 23 covers the first upper surface 22a of the base planar spiral coil 22.

The build-up coil layer 2c includes a build-up planar spiral coil 25 (made of metal material) having a fourth upper surface 25a and a fourth lower surface 25b opposing the fourth upper surface 25a, and includes a third insulating layer 27 having a fifth upper surface 27a and a fourth lower surface 25b opposing the fifth upper surface 27a and covering the build-up planar spiral coil 25, wherein the fourth upper surface 25a of the build-up planar spiral coil 25 and a side circumference thereof are covered with at least one electroplated growth layer (made of metal material) 26, 26a, and the fifth lower surface 27b of the third insulating layer 27 is stacked on and bonded to the third upper surface 23a of the second insulating layer 23.

The opening 28 includes a through hole penetrating the base coil layer 2a, the conductive layer 2b and the build-up coil layers 2c, 3c.

In an embodiment, the at least one build-up coil layer is a multiple-layer stacked build-up coil layer, and each third insulating layer 37 in a relatively lower layer of the build-up coil layer 3c (i.e., a lower layer of the multiple layer stacked build-up layer) further includes at least one conductor 350 having the same composition as the build-up planar spiral coil 25 and connecting a fourth upper surface 25a of the build-up planar spiral coil 25 that is below conductor 350 to the build-up planar spiral coil 35 that is above the conductor 350.

In an embodiment, a relatively uppermost layer of the build-up coil layer 3c further includes at least one external electrical connection pad 351 having the same composition as the build-up planar spiral coil 35 and disposed within the third insulating layer 37, wherein the upper surface of the external electrical connection pad 351 is exposed from the third insulating layer 37 of the relatively uppermost layer of the build-up coil layer 3c.

In an embodiment, the second lower surface 21b of the first insulating layer 21 is bonded to a lower insulating layer 29.

In an embodiment, the first insulating layer 21 includes a photosensitive dielectric material, and the second insulating layer 23 and/or the third insulating layer 27, 37 include(s) a thermosetting dielectric material.

In an embodiment, the base planar spiral coil 21, the conductor 250, the build-up planar spiral coil 25, 35 and/or the electroplated growth layer 26, 36 include(s) copper or a copper alloy.

In an embodiment, the compositions of the electroplated growth layer 26, 36 and the build-up planar spiral coil 25, 35 are the same or different.

In an embodiment, the first upper surface 22a of the base planar spiral coil 22 protrudes from, is flush with, or is recessed into the second upper surface 21a of the first insulating layer 21.

In summary, in the coil carrier board and manufacturing method thereof of the present disclosure, the first insulating layer, the second insulating layer and the spiral coil are manufactured mainly by a build-up circuit process, such that the overall structure of the coil carrier board has extremely flatness, and the alignment accuracy between the layers is extremely high, and it is easy to manufacture fine line width/fine line spacing, therefore, the present disclosure is capable of obtaining a miniaturized coil carrier board with better flatness and higher alignment accuracy.

Furthermore, the use of a photosensitive dielectric material as the first insulating layer facilitates the manufacture of high aspect ratio patterned plural openings for the attachment and forming of electroplated metals. Hence, the present disclosure is able to manufacture a base planar spiral coil with optimized features such as copper thickness and fine pitch, thereby effectively enhancing the high current-carrying efficiency of the coil carrier board.

In addition, a horizontal build-up planar spiral coil having electroplated growth layers can effectively increase the copper thickness and reduce the copper layer spacing by multiple copper electroplating processes, thereby effectively enhancing the high current-carrying efficiency of the coil carrier board.

Furthermore, the present disclosure adopts a thermosetting dielectric material as the second insulating layer to strengthen the rigidity of the coil carrier board, thereby avoiding the problem of misalignment during the assembly of the electronic products. Therefore, the coil carrier board of the present disclosure is structurally rigid and can be introduced into the automated production line of the electronic product to achieve the purpose of the automated assembly production of the electronic products.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A coil carrier board, comprising:
a base coil layer including a base planar spiral coil made of metal material and having a first upper surface and a first lower surface opposing the first upper surface, and a first insulating layer having a second upper surface and a second lower surface opposing the second upper surface and covering the base planar spiral coil, wherein the first upper surface of the base planar spiral coil is exposed from the second upper surface of the first insulating layer, and the first lower surface of the base planar spiral coil is exposed from the second lower surface of the first insulating layer;
a conductive layer stacked on and bonded to the base coil layer, including:
a conductor made of metal material having a first upper end surface and a first lower end surface opposing the first upper end surface, and
a second insulating layer having a third upper surface and a third lower surface opposing the third upper surface and covering the conductor, wherein the first upper end surface of the conductor is exposed from the third upper surface of the second insulating layer, the first lower end surface of the conductor is bonded to the first upper surface of the base planar spiral coil, a composition of the second insulating layer is different from that of the first insulating layer, the third lower surface of the second insulating layer is stacked on and bonded to the second upper surface of the first insulating layer, and the second insulating layer covers the first upper surface of the base planar spiral coil;
at least one build-up coil layer stacked on and bonded to the conductive layer, including:
a build-up planar spiral coil made of metal material and having a fourth upper surface and a fourth lower surface opposing the fourth upper surface, and
a third insulating layer having a fifth upper surface and a fifth lower surface opposing the fifth upper surface and covering the build-up planar spiral coil, wherein the fourth lower surface of the build-up planar spiral coil is bonded to the third upper surface of the second insulating layer, the fourth upper surface of the build-up planar spiral coil and a side circumference thereof are covered by at least one electroplated growth layer formed by metal material, and the fifth lower surface of the third insulating layer is stacked on and bonded to the third upper surface of the second insulating layer; and
an opening penetrating the base coil layer, the conductive layer, and the build-up coil layer.

2. The coil carrier board of claim 1, wherein the at least one build-up coil layer is a multiple-layer stacked build-up coil layer, and each third insulating layer in a relatively lower layer of the build-up coil layer further includes at least one conductor having the same composition as the build-up planar spiral coil and connecting the build-up planar spiral coil that is below the conductor to the build-up planar spiral coil that is above the conductor.

3. The coil carrier board of claim 1, wherein a relatively uppermost layer of the build-up coil layer further includes at least one external electrical connection pad having the same composition as the build-up planar spiral coil and disposed within the third insulating layer, wherein an upper surface of the external electrical connection pad is exposed from the fifth upper surface of the third insulating layer of the relatively uppermost layer of the build-up coil layer.

4. The coil carrier board of claim 2, wherein a relatively uppermost layer of the build-up coil layer further includes at least one external electrical connection pad having the same composition as the build-up planar spiral coil and disposed within the third insulating layer in the relatively uppermost layer, wherein an upper surface of the external electrical connection pad is exposed from the fifth upper surface of the third insulating layer of the relatively uppermost layer of the build-up coil layer.

5. The coil carrier board of claim 1, wherein the second lower surface of the first insulating layer is further bonded to a lower insulating layer including an insulating material.

6. The coil carrier board of claim 2, wherein the second lower surface of the first insulating layer is further bonded to a lower insulating layer including an insulating material.

7. The coil carrier board of claim 1, wherein the first insulating layer includes a photosensitive dielectric material, and the second insulating layer and/or the third insulating layer include(s) a thermosetting dielectric material.

8. The coil carrier board of claim 1, wherein the base planar spiral coil, the conductor of metal material, the build-up planar spiral coil and/or the electroplated growth layer include(s) copper or a copper alloy.

9. The coil carrier board of claim 1, wherein compositions of the electroplated growth layer and the build-up planar spiral coil are the same or different.

10. The coil carrier board of claim 1, wherein the first upper surface of the base planar spiral coil protrudes from, is flush with, or is recessed into the second upper surface of the first insulating layer.

11. A method of manufacturing a coil carrier board, comprising:
step 1, providing a carrier board having a metallic surface;
step 2, forming a first insulating layer having patterned plurality of openings on the carrier board;
step 3, forming a base planar spiral coil by electroplating in the patterned plurality of openings, wherein an upper surface of the base planar spiral coil is exposed from an upper surface of the first insulating layer;
step 4, forming a second insulating layer on the first insulating layer and the base planar spiral coil, wherein the second insulating layer covers an upper surface of the base planar spiral coil, and a composition of an insulating material of the second insulating layer is different from that of an insulating material of the first insulating layer;
step 5, forming at least one aperture in an upper surface of the second insulating layer to expose a portion of the upper surface of the base planar spiral coil;
step 6, performing a surface metallization process to form a metallized surface on the upper surface of the second insulating layer and within the aperture;
step 7, forming a build-up planar spiral coil on the second insulating layer and forming a conductor in the aperture for connecting the build-up planar spiral coil to the base planar spiral coil by electroplating on the metallized surface of the second insulating layer and the aperture by means of a patterned exposure developing process, wherein the build-up planar spiral coil and the conductor are of the same composition;
step 8, performing an etching process to remove a material of the metallized surface on the second insulating layer that is not covered by the build-up planar spiral coil;
step 9, forming an electroplated growth layer on exposed surfaces of the build-up planar spiral coil by performing an electroplating process to make the build-up planar spiral coil taller, wider and shorter in line pitch, wherein the number of repetitions of step 9 can be increased optionally to form a stack of a plurality of electroplated growth layers;
step 10, forming a third insulating layer on the second insulating layer to cover the second insulating layer and the build-up planar spiral coil;
step 11, removing the carrier board to expose a lower surface of the base planar spiral coil and a lower surface of the first insulating layer; and
step 12, forming a through hole through the first insulating layer, the second insulating layer and the third insulating layer to form an opening.

12. The method of claim 11, wherein prior to performing step 11, step 10 further comprises performing the following steps:
step 10-1, forming at least one aperture in the third insulating layer to expose a portion of an upper surface of the build-up planar spiral coil;
step 10-2, performing a surface metallization process to form a metallized surface on an upper surface of the third insulating layer and within the aperture;
step 10-3, forming another build-up planar spiral coil and a conductor connecting the another build-up planar spiral coil to the build-up planar spiral coil that is below the another build-up planar spiral coil by electroplating on the metallized surface of the third insulating layer and the aperture by means of a patterned exposure developing process;
step 10-4: performing an etching process to remove a metal material on the metallized surface of the third insulating layer that is not covered by the another build-up planar spiral coil, so as to expose an insulating surface of the third insulating layer;
step 10-5, forming another electroplated growth layer on exposed surfaces of the another build-up planar spiral coil by performing an electroplating process to make the another build-up planar spiral coil taller, wider and shorter in line pitch, wherein the number of repetitions of step 10-5 can be increased optionally to form a stack of a plurality of another electroplated growth layer;
step 10-6, forming another third insulating layer to cover the another build-up planar spiral coil formed in step 10-3 through step 10-5; and
step 10-7, optionally increasing the number of repetitions of steps 10-1 through step 10-6 to form a stack of a plurality of the another build-up planar spiral coil and the another third insulating layer.

13. The method of claim 11, wherein at least one external electrical connection pad is formed by simultaneous electroplating during a formation of the build-up planar spiral coil in an uppermost layer, and an upper surface of the external electrical connection pad is exposed from an upper surface of the third insulating layer in the uppermost layer.

14. The method of claim 12, wherein at least one external electrical connection pad is formed by simultaneous electroplating during a formation of the build-up planar spiral coil in an uppermost layer, and an upper surface of the external electrical connection pad is exposed from an upper surface of the third insulating layer in the uppermost layer.

15. The method of claim 11, further comprising prior to performing step 12, forming a lower insulating layer to cover the lower surface of the first insulating layer.

16. The method of claim 11, wherein the upper surface of the second insulating layer in step 5 is a metallic surface or a non-metallic surface.

17. The method of claim 12, wherein the upper surface of the third insulating layer in step 10-2 is a metallic surface or a non-metallic surface.
